(19) United States
(12) Patent Application Publication
(10) Pub. No.: US 2026/0129770 A1
(43) Pub. Date: May 7, 2026

(54) SPRAY PYROLYSIS DEPOSITION OF DIELECTRIC LINERS FOR TGV

(71) Applicant: Intel Corporation, Santa Clara, CA (US)

(72) Inventor: Sriram DATTAGURU, Chandler, AZ (US)

(21) Appl. No.: 18/939,574

(22) Filed: Nov. 7, 2024

(51) Int. Cl. H05K 3/28; C23C 4/129; H01L 23/15; H05K 1/03; H05K 1/11; H05K 3/00

(52) U.S. Cl. CPC H05K 3/28; H05K 1/0306; H05K 1/115; H05K 3/0011; C23C 4/129; H10W 70/692

(57) ABSTRACT

According to the various aspects, a method is disclosed that includes providing a substrate with a plurality of through hole vias disposed in the substrate and each through hole via having an interior sidewall. The substrate may be disposed on a support in a spray pyrolysis tool. In an aspect, the substrate may be preheated and a precursor solution may be dispensed towards the sidewalls of the plurality of through hole vias. The heating of the precursor solution results in the forming of a dielectric liner on the sidewalls. In another aspect, a device having a glass core with a plurality of through hole vias that form sidewalls disposed in the substrate, a dielectric liner having a grain size in a range of approximately 20 nm to 500 nm, and a conductive material filling the plurality of through hole vias.

### BACKGROUND

As semiconductor technology advances, the need to improve performance and lower costs for integrated circuit design and fabrication are constant challenges. It is becoming more difficult and costly to realize high-volume manufacturing for semiconductors as transistors continue to shrink in size. Cost savings may be potentially realized by building more efficient structures and using materials that improve power performance.

In terms of dimensional and performance stability, silicon and glass are better suited for fine-pitch interconnects with high input/output (I/O) density than organic substrates. However, as a semiconductor interconnect structure, silicon and glass substrates may require the deposition of dielectric layers, which raises production costs. On the other hand, as an insulating material, glass has become an attractive support material for advanced manufacturing and packaging due to its adjustable coefficient of thermal expansion (CTE), excellent surface flatness, high resistivity, and low cost. Therefore, glass has emerged as the material of choice in recent years for a new generation of semiconductor devices.

It is common to use through-glass-vias (TGVs) and microvias as the interconnects between layers in high-density interconnect substrates and printed circuit boards (PCBs) to accommodate the high I/O density of advanced packages. The use of three-dimensional (3D) interconnects with TGV technology has wide applicability in radio frequency (RF) devices, optoelectronic systems, and multi-layer glass substrates. It is customary to have a metal oxide (i.e., dielectric) adhesion promotion layer on the through hole vias and glass surface that allows for electroless copper (Cu) to be plated directly on the glass as a seed layer, followed by a thicker electrolytic copper to be plated on top. However, the costs of the equipment for producing such insulative liners, such as sputtering or atomic layer deposition tools, are high and their throughput times are relatively slow. It is therefore important to have solutions that are able to improve the mechanical performance/stability of the through hole vias and reduce the cost of manufacture.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of through hole vias having insulative coatings/linings according to an aspect of the present disclosure;

FIG. 2 shows exemplary representations of a present coating tool for producing the insulative coatings/linings for the through hole vias according to an aspect of the present disclosure;

FIG. 3 shows a simplified flow diagram for an exemplary method according to an aspect of the present disclosure; and

FIG. 4 shows an exemplary representation of through hole vias having a metal filling to form a plurality of interconnects.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present device having a coating or liner of insulative/dielectric material may be produced by a low-cost spray pyrolysis tool and method. The present spray pyrolysis method is adapted for use with glass cores and glass substrates. In an aspect, the spray pyrolysis method may be a cost-effective, reproducible method, and able to coat complex geometries. In addition, the present method may be easily integrated into standard substrate/glass core process flows for high-volume manufacturing.

The present disclosure is directed to a method that includes providing a substrate with a plurality of through hole vias disposed in the substrate and each through hole via having an interior sidewall. The substrate may be disposed on a support in a coating tool, i.e., a spray pyrolysis tool. In an aspect, the substrate may be preheated using a heating element in the support and a precursor solution may be dispensed towards the sidewalls of the plurality of through hole vias. The heating of the precursor solution results in the forming of a dielectric liner on the sidewalls.

The present disclosure is also directed to a product made by a process that includes providing a substrate with a plurality of through hole vias disposed in the substrate and each through hole via having an interior sidewall. The substrate may be disposed on a support in a coating tool, i.e., a spray pyrolysis tool. In an aspect, the substrate may be preheated using a heating element in the support and a precursor solution may be dispensed towards the sidewalls of the plurality of through hole vias using the spray pyrolysis tool. The heating of the precursor solution results in the forming of a dielectric liner on the sidewalls. In an aspect, the dielectric liner may have a grain size in a range of approximately 20 nm to 500 nm and may have a thickness in a range of approximately 0.1 μm to 2 μm. In another aspect, the dielectric liner may have a grain size in a range of approximately 20 nm to 200 nm and may have a thickness in a range of approximately 0.1 μm to 1 μm.

The present disclosure is also directed to a device having a glass core with a plurality of through hole vias that form sidewalls disposed in the substrate, a dielectric liner having a grain size in a range of approximately 50 nm to 500 nm, and a conductive material filling the plurality of through hole vias. In an aspect, the dielectric liner has a thickness in a range of approximately 0.5 μm to 2 μm and is substantially free of impurities.

The technical advantages of the present disclosure include, but are not limited to:
(i) providing a simple and scalable solution for producing dielectric liners for through glass vias (TGVs) using a method that requires using a relatively low-cost tool;
(ii) providing high-quality dielectric liners that may be deposited on complex geometries; and
(iii) providing methods for forming dielectric lines in the TGVs that are compatible with high-volume manufacturing requirements.

To more readily understand and put into practical effect the present devices with through hole via interconnects having dielectric/insulative liners in the vias and methods for their manufacture using spray pyrolysis tools, which may provide improved glass substrates in devices, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

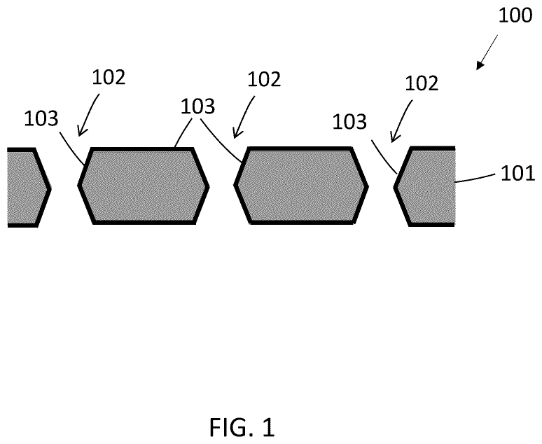

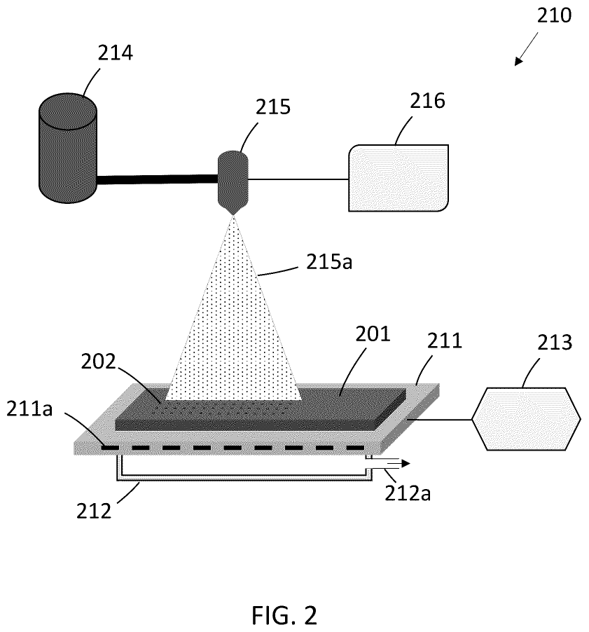

FIG. 1 shows an exemplary representation of a device 100 with a plurality of through hole vias 102 according to an aspect of the present disclosure. In this aspect, the device 100 may have a glass substrate 101, which may be part of a larger glass panel, and the through hole vias will be through glass vias (TGVs) 102. In an aspect, the TGVs 102 may have a dielectric or insulative liner 103 that is formed by a spray pyrolysis tool, as shown in FIG. 2. A high-quality liner of dielectric/oxide nanoparticles may be deposited on the glass substrate 101 including both on the top and bottom surfaces of the glass substrate 101 and tapered surfaces of the TGVs. In an aspect, using the spray pyrolysis tool, the dielectric liner 103 may have a grain size in a range of approximately 20 nm to 200 nm and may have a thickness in a range of approximately 0.1 μm to 1 μm.

FIG. 2 shows exemplary representations of a present coating tool for producing the insulative coatings/linings for the through hole vias according to an aspect of the present disclosure. The present coating tool may be a spray pyrolysis tool 210 that includes a chamber (not shown) having a substrate support 211 with a built-in heating element 211a, a vacuum component 212 (which may be optional), a temperature control unit 213, a precursor solution provided from a storage unit 214 connected to a dispenser 215 (which may be connected to a compressed air supply (not shown)), and a dispenser (atomizer) control unit 216. The present spray pyrolysis tool 210 may be a standalone programmable three-axis robot ultrasonic full coating solution having a single or multiple nozzle dispensers 215, including an array of multiple dispensers/nozzles (not shown).

In an aspect shown in FIG. 2, a glass substrate 201 may be positioned on the support 211, which may be sized to accommodate from small to large substrates. The glass substrate 201 may have a plurality of through glass vias 202 formed therein. In an aspect, a present spray pyrolysis tool 210 may be used for processing existing 510×515 mm panels, which are commonly used in the semiconductor package substrate industry, and the throughput can be increased by using multiple nozzles, nozzle lines, etc.

The support 211 may be used to pre-heat the glass substrate 201 to a predetermined temperature set by the temperature control unit 213. In an aspect, the support 211 may be preheated to a temperature in a range of approximately 300 to 500° C., and in turn, the glass substrate 201 may be heated to a temperature in the range of 200 to 400° C. by the support 211. In an aspect, a predetermined temperature of approximately 350° C. may be set by the temperature control unit 213. Unlike organic substrates, glass substrates can withstand high temperatures in a range of approximately 300 to 450° C. The heating element 211a may be heating coils, a heating plate, and/or electric resistance elements that are built into the support 211.

The present spray pyrolysis tool 210 performs a process that is able to deposit a thin film by spraying a precursor solution, shown in FIG. 2 as a spray 215a, on a heated surface of the glass substrate 201, where the chemical constituents of the precursor solution react at or before reaching the glass substrate 201 to form a desired chemical compound, i.e., a dielectric. The chemical constituents are selected such that the desired chemical compound is deposited, while the undesired compounds remain volatile at the temperature of deposition and are removed. The present spray pyrolysis tool 210 may not require a high vacuum or a very clean environment as operating conditions. The throughput time for this process may be approximately 60 seconds per substrate/panel or less if multiple sprayers are installed in the chamber of the spray pyrolysis tool 210.

In an aspect, the precursor solution may be formed by dissolving a chemical constituent, which may be a metal chloride (e.g., zinc chloride (ZnCl₂), titanium tetrachloride (TiCl₄)) in deionized water that is dispensed from the storage unit 214. The present precursor solutions may include aqueous solutions of metal salts of nitrates, chlorides, and/or acetates. In an aspect, the present spray pyrolysis process for depositing dielectric liners on TGVs may use, as the chemical constituents, titanium (Ti), zinc (Zn), and silicon (Si) to produce, respectively, dielectric liners made of titanium dioxide (TiO₂), zinc oxide (ZnO) and silicon dioxide (SiO₂).

In another aspect, the precursor solution may have chemical constituents that are selected such that the undesired compounds remain volatile at the temperature of deposition and are removed. The undesirable volatile compounds may form during heterogeneous reactions of a metal chloride, nitrate, or acetates in the vapor phase and/or at a glass substrate and TGV surfaces and are volatile compounds, such as hydrochloric acid (HCl), nitric acid (HNO₃), water (H₂O), that are removed while in gaseous form. For example, a precursor solution of zinc chloride salt may have a reaction shown as:

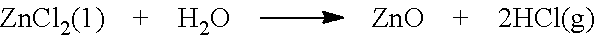

and the by-product of HCl in gaseous form may be collected and removed by an exhaust system (not shown), which may be a component of the spray pyrolysis tool 210.

In an aspect, the dispenser 215 may be an aerosol sprayer/atomizer or ultrasonic sprayer that produces the spray 215a of the precursor solution over the glass substrate 201. The droplet size of the spray 215a may depend on the method of atomization. In addition, the precursor solution concentration, deposition temperature, and droplet size are important parameters to control the grain size, surface morphology, and thickness of a present dielectric liner. The precursor concentration may have, for example, a range of between approximately 5 g/liter to 300 g/liter based on the output parameter targeted. For example, an aerosol sprayer may produce a larger size droplet (e.g., over 50 μm) and larger grain size (e.g., over 200 nm), while an ultrasonic sprayer may produce smaller droplets (e.g., 2 μm to 40 μm) and smaller grain (e.g., over 200 nm) in a dielectric liner. In an aspect, the present droplet size may have a range of approximately 2 μm to 50 μm. It should be understood that various precursor concentrations and droplet sizes that may be used will also depend on the glass substrate size and the pitch and size of the TGVs (i.e., the TGV density in the glass substrate).

In an aspect, to ensure that the droplets from the spray 215a reach the backside of the glass substrate 201, a vacuum be applied to the backside, and/or the spray operation may be repeated as a second deposition after flipping the glass substrate 201 over. However, depending on the deposition coverage, the glass substrate 201 may need to be annealed and cooled to relieve any induced stress before the second deposition.

As shown in FIG. 2, the vacuum component 212 may be disposed under the support 211, which may have a plurality of openings (not shown) that provide the vacuum to the backside of the glass substrate 201 by way of a vacuum inlet 212a that is coupled to a pump system (not shown).

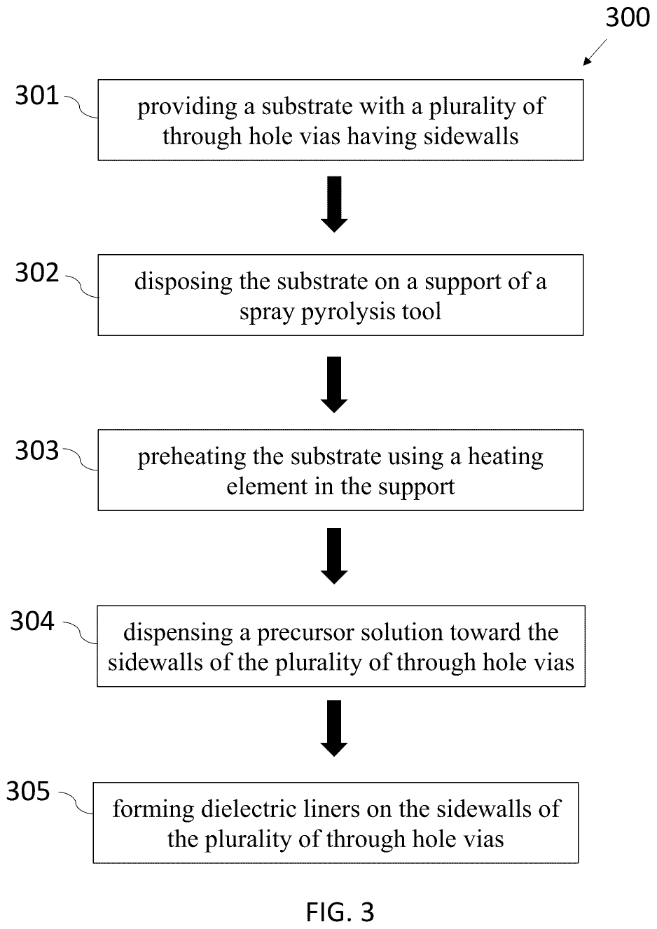

FIG. 3 shows a simplified flow diagram for an exemplary method according to an aspect of the present disclosure.

The operation 301 may be directed to providing a substrate with a plurality of through hole vias having sidewalls.

The operation 302 may be directed to disposing the substrate on a support of a spray pyrolysis tool.

The operation 303 may be directed to preheating the substrate using a heating element in the support.

The operation 304 may be directed to dispensing a precursor solution toward the sidewalls of the plurality of through hole vias.

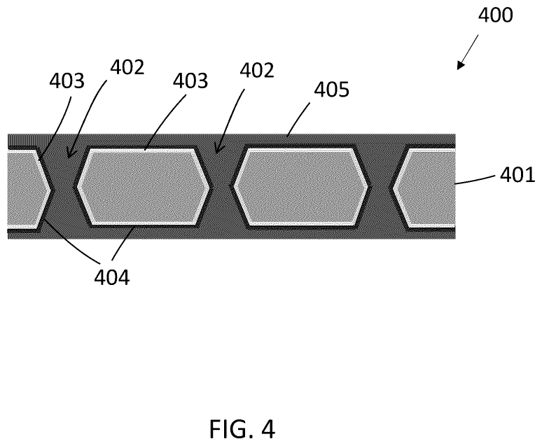

The operation 305 may be directed to forming dielectric liners on the sidewalls of the plurality of through hole vias. The through hole vias may be subsequently filled with a conductive material to complete the interconnect vias for a device as shown in FIG. 4.

FIG. 4 shows an exemplary representation of a device 400 having a glass substrate 401 with a plurality of through hole vias (TGVs) 402. In an aspect, the TGVs 402 may have a dielectric liner 403 that is formed by a spray pyrolysis tool, as shown in FIG. 2, which is deposited on the top and bottom surfaces of the glass substrate 401 and tapered surfaces of the TGVs 402. The dielectric liner 403 promotions adhesion on the surfaces of through hole vias 402 and glass substrate for electroless deposition of copper (Cu) as a seed layer 404. Thereafter, a thicker electrolytic copper layer 405 may be deposited on top of the seed layer 404 using a conventional deposition method.

It will be understood that any property described herein for a particular device with through hole vias having insulative linings in the vias and/or method for forming the insulative linings may also hold for any devices using the present methods described herein. It will also be understood that any property described herein for a specific method may hold for any of the methods described herein. Furthermore, it will be understood that for any device and the methods described herein, not necessarily all the components or operations described will be shown in the accompanying drawings or method, but only some (not all) components or operations may be disclosed.

To more readily understand and put into practical effect the present devices with through hole via interconnects having dielectric liners in the vias and present methods for forming the devices having present dielectric liners, they will now be described by way of examples. For the sake of brevity, duplicate descriptions of features and properties may be omitted.

### EXAMPLES

Example 1 provides a method that includes providing a substrate with a plurality of through hole vias disposed in the substrate, for which each through hole via includes a sidewall, disposing the substrate on a support in a coating tool, preheating the substrate using a heating element in the support, dispensing a precursor solution towards the sidewalls of the plurality of through hole vias, and forming a dielectric liner on the sidewalls.

Example 2 may include the method of example 1 and/or any other example disclosed herein, for which the coating tool includes a spray pyrolysis tool.

Example 3 may include the method of example 1 and/or any other example disclosed herein, for which the dispensing of the precursor solution further includes providing droplets having a size in a range of approximately 2 μm to over 50 μm.

Example 4 may include the method of example 3 and/or any other example disclosed herein, which further includes using an aerosol sprayer to dispense the precursor solution.

Example 5 may include the method of example 3 and/or any other example disclosed herein, which further includes using an ultrasonic sprayer to dispense the precursor solution.

Example 6 may include the method of example 1 and/or any other example disclosed herein, which further includes heating the dispensed precursor solution to a temperature range of approximately 200 to 400° C.

Example 7 may include the method of example 6 and/or any other example disclosed herein, which further includes removing impurities during the heating of the dispensed precursor solution.

Example 8 may include the method of example 6 and/or any other example disclosed herein, for which the support is preheated to a temperature range of approximately 300 to 500° C.

Example 9 may include the method of example 1 and/or any other example disclosed herein, for which the substrate having the plurality of through hole vias includes a topside surface and a backside surface, and for which the method further includes dispensing the precursor solution on the topside surface of the substrate to form the dielectric liner, turning over the substrate, and dispensing the precursor solution on the backside surface of the substrate to form the dielectric liner.

Example 10 may include the method of example 1 and/or any other example disclosed herein, for which the support further includes a vacuum feature and for which the method further includes using the vacuum feature to apply a vacuum on the plurality of through hole vias while dispensing the precursor solution towards the sidewalls of the plurality of through hole vias.

Example 11 provides a product made by a process that includes providing a substrate with a plurality of through hole vias disposed in the substrate, for which each through hole via includes a sidewall, disposing the substrate on a support of a spray pyrolysis tool, preheating the substrate using a heating element in the support, dispensing a precursor solution towards the sidewalls of the plurality of through hole vias using the spray pyrolysis tool, and forming a dielectric liner on the sidewalls.

Example 12 may include the product of example 11 and/or any other example disclosed herein, for which the dielectric liner has a grain size in a range of approximately 20 nm to 500 nm.

Example 13 may include the product of example 11 and/or any other example disclosed herein, for which the dielectric liner has a thickness in a range of approximately 0.1 μm to 2 μm.

Example 14 may include the product of example 11 and/or any other example disclosed herein, for which the precursor solution includes a metal salt.

Example 15 may include the product of example 11 and/or any other example disclosed herein, for which the process further includes heating the dispensed precursor solution to a temperature range of approximately 200 to 400° C.

Example 16 may include the product of example 15 and/or any other example disclosed herein, for which the process further includes removing impurities during the heating of the dispensed precursor solution.

Example 17 may include the product of example 11 and/or any other example disclosed herein, for which the process of dispensing the precursor solution further includes providing droplets having a size in a range of approximately 2 μm to over 50 μm.

Example 18 provides a device including a glass core/substrate with a plurality of through hole vias disposed in the glass core, for which each through hole via includes a sidewall, a dielectric liner having a grain size in a range of approximately 20 nm to 500 nm on the sidewall, and a conductive material filling the plurality of through hole vias.

Example 19 may include the device of example 18 and/or any other example disclosed herein, for which the dielectric liner has a thickness in a range of approximately 0.1 μm to 2 μm.

Example 20 may include the device of example 18 and/or any other example disclosed herein, for which the dielectric liner is substantially free of impurities.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A method comprising:
providing a substrate with a plurality of through hole vias disposed in the substrate, wherein each through hole via comprises a sidewall;
disposing the substrate on a support in a coating tool;
preheating the substrate using a heating element in the support;
dispensing a precursor solution towards the sidewalls of the plurality of through hole vias; and
forming a dielectric liner on the sidewalls.

2. The method of claim 1, wherein the coating tool comprises a spray pyrolysis tool.

3. The method of claim 1, wherein the dispensing of the precursor solution further comprises providing droplets having a size in a range of approximately 2 μm to over 50 μm.

4. The method of claim 3, further comprises using an aerosol sprayer to dispense the precursor solution.

5. The method of claim 3, further comprises using an ultrasonic sprayer to dispense the precursor solution.

6. The method of claim 1, further comprises heating the dispensed precursor solution to a temperature range of approximately 200 to 400° C.

7. The method of claim 6, further comprises removing impurities during the heating of the dispensed precursor solution.

8. The method of claim 6, wherein the support is preheated to a temperature range of approximately 300 to 500° C.

9. The method of claim 1, wherein the substrate having the plurality of through hole vias comprises a topside surface and a backside surface, and wherein the method further comprises dispensing the precursor solution towards the topside surface of the substrate to form the dielectric liner, turning over the substrate, and dispensing the precursor solution towards the backside surface of the substrate to form the dielectric liner.

10. The method of claim 1, wherein the support further comprises a vacuum feature and wherein the method further comprises using the vacuum feature to apply a vacuum on the plurality of through hole vias while dispensing the precursor solution towards the sidewalls of the plurality of through hole vias.

11. A product made by a process comprising:
providing a substrate with a plurality of through hole vias disposed in the substrate, wherein each through hole via comprises a sidewall;
disposing the substrate on a support of a spray pyrolysis tool;
preheating the substrate using a heating element in the support;
dispensing a precursor solution towards the sidewalls of the plurality of through hole vias using the spray pyrolysis tool; and
forming a dielectric liner on the sidewalls.

12. The product of claim 11, wherein the dielectric liner has a grain size in a range of approximately 20 nm to 500 nm.

13. The product of claim 11, wherein the dielectric liner has a thickness in a range of approximately 0.1 μm to 2 μm.

14. The product of claim 11, wherein the precursor solution comprises a metal salt.

15. The product of claim 11, wherein the process further comprises heating the dispensed precursor solution to a temperature range of approximately 200 to 400° C.

16. The product of claim 15, wherein the process further comprises removing impurities during the heating of the dispensed precursor solution.

17. The product of claim 11, wherein the process of dispensing the precursor solution further comprises providing droplets having a size in a range of approximately 2 μm to over 50 μm.

18. A device comprising:
a glass core comprising a plurality of through hole vias disposed in the glass core, wherein each through hole via comprises a sidewall;
a dielectric liner having a grain size in a range of approximately 20 nm to 500 nm on the sidewall; and
a conductive material filling the plurality of through hole vias.

19. The device of claim 18, wherein the dielectric liner has a thickness in a range of approximately 0.1 μm to 2 μm.

20. The device of claim 18, wherein the dielectric liner is substantially free of impurities.
